(19) United States
(12) Patent Application Publication
(10) Pub. No.: US 2026/0163564 A1
(43) Pub. Date: Jun. 11, 2026

(54) POWER SEMICONDUCTOR MODULE FOR A TRACTION CONVERTER

(71) Applicant: ZF Friedrichshafen AG, Friedrichshafen (DE)

(72) Inventors: Oliver Krone, Fleischwangen (DE); Manuel Schwab, Friedrichshafen (DE)

(73) Assignee: ZF Friedrichshafen AG, Friedrichshafen (DE)

(21) Appl. No.: 19/413,549

(22) Filed: Dec. 9, 2025

(30) Foreign Application Priority Data
Dec. 9, 2024 (DE) 10 2024 211 707.2

(51) Int. Cl. H03K 17/082; B60L 15/00; H02M 7/00; H05K 1/16

(52) U.S. Cl. CPC H03K 17/0822; B60L 15/007; H02M 7/003; H05K 1/165; H05K 2201/10909

(57) ABSTRACT

A power semiconductor module for a traction converter includes a semiconductor switch with a drain terminal, source terminal, Kelvin source terminal, and gate terminal, a first driver path for connecting the gate terminal to a driver circuit, and a second driver path for connecting the source terminal to the driver circuit, in order to switch the semiconductor switch, a source path between the Kelvin source terminal and the source terminal, wherein the source path contains an additional source terminal, and wherein the source path forms a parasitic inductor between the Kelvin source terminal and the additional source terminal, and a resistor unit in the second driver path that is connected in parallel to the parasitic inductor to conduct voltage generated by the parasitic inductor during a current-changing phase to the driver circuit to limit the current change rate while switching the semiconductor switch.

### CROSS-REFERENCE TO RELATED APPLICATION

This application claims priority to German Patent Application No. 10 2024 211 707.2, filed on Dec. 9, 2024, the entirety of which is hereby fully incorporated by reference herein.

### TECHNICAL FIELD

The present disclosure relates to a power semiconductor module for a traction converter. The present disclosure also relates to a traction converter for a vehicle.

### BACKGROUND

The power electronics in electric and hybrid vehicles conduct electricity from the battery to the electric motor and convert direct current into alternating current. There is an AC converter, inverter, or traction converter for this. Transistors or other power semiconductors are normally used for this, which are in a power semiconductor module and switched in short and regular intervals. MOSFETs (metal-oxide-semiconductor field-effect transistors) and IGBTs (insulated-gate bipolar transistors) are used as the switches. When switched on, electricity is conducted from the battery to the motor. An AC voltage is generated by high-frequency switching, which is then converted in the electric motor to traction power. Numerous power semiconductors are normally connected in parallel in a switch to increase the ampacity.

A half-bridge circuit containing numerous semiconductor switches is normally used to generate the AC voltage necessary for operating an electric motor. Switching losses may occur inside individual semiconductor switches that can be reduced by increasing the switching speed. These higher switching frequencies, however, also result in increased demands on the components and circuits that are used.

The high-frequency switching in power semiconductors such as MOSFETs and IGBTs results in strong di/dt and dv/dt switching edges that can cause electromagnetic emissions. Approaches reducing the electromagnetic emissions are necessary to satisfy the power requirements and ensure the necessary safety.

Another problem with quick switching in power semiconductors is voltage surges occurring when switching off. These voltage surges occur when switching off power semiconductors, in particular in the case of inductive leakages. When interrupting the current flow with a semiconductor switch, the electricity stored in the inductor cannot be immediately dissipated. This results in voltage peaks over the semiconductors that can exceed the nominal voltage for the component. These excess voltages are problematic because they can break or permanently damage the semiconductors. Furthermore, switches may be unintentionally activated if the voltage peaks trigger parasitic effects that act on adjacent power semiconductors.

One method for reducing electromagnetic emissions and limiting these voltage surges in power semiconductors involves increasing the gate resistance in the gate-driver circuit. Increasing the gate resistance slows the switching process, thus reducing the switching edges. This reduces electromagnetic emissions, and limits voltage surges, but has the disadvantage that the switching losses are increased, because the switching edges are less steep, thus impacting the efficiency.

DE 100 32 196 A1 discloses a suppressor circuit for MOSFET switches. MOSFET switches have a gate terminal, drain terminal and source terminal. The MOSFET switch is activated via the gate terminal. What is important here is that there is a capacitive component between the drain and gate terminals.

### SUMMARY

A fundamental object of the present disclosure is to reduce switching losses in a power semiconductor module for a traction converter and minimize electromagnetic emissions.

A first aspect of the present disclosure therefore relates to a power semiconductor module for a traction converter, comprising:
a semiconductor switch with a drain terminal, source terminal, Kelvin source terminal, and gate terminal;
a first driver path for connecting the gate terminal to a driver circuit for switching the semiconductor switch;
a source path between the Kelvin source terminal and the source terminal that contains an additional source terminal, in which the source path forms a parasitic inductor between the Kelvin source terminal and the additional source terminal; and
a resistor unit in the second driver path connected in parallel to the parasitic inductor to conduct voltage generated by the parasitic inductance during a current-conversion phase to the driver circuit, in order to limit the rate at which the current changes during the switching process.

Another aspect of the present disclosure relates to a traction converter for a vehicle that contains the power semiconductor module described above.

Preferred embodiments of the present disclosure are described herein. It is understood that the features specified above and described below can be used not only in the given combinations, but also in other combinations or in and of themselves, without abandoning the framework of the present disclosure.

The present disclosure relates to a power semiconductor module for a traction converter. The power semiconductor module contains a semiconductor switch with a drain terminal, source terminal, Kelvin source terminal, and gate terminal. The power semiconductor module also contains a first driver path connecting the gate terminal to a driver circuit, and a second driver path connecting the source terminal to the driver circuit, for switching the semiconductor switch. The power semiconductor module also contains a source path between the Kelvin source terminal and the source terminal. The source path has an additional source terminal. The source path forms a parasitic inductor between the Kelvin source terminal and the additional source terminal. The power semiconductor module also contains a resistor unit in the second driver path that is connected in parallel to the parasitic inductor to conduct voltage generated by the parasitic inductor during a current change phase to the driver circuit, in order to limit the current change rate (di/dt) while switching the semiconductor switch.

Source voltage can be accessed separately by the Kelvin source terminal, independently of the main current path, which contains undesired parasitic inductances. As a result of this separation, voltage drop and parasitic effects can be reduced.

Voltage generated during a current change phase is conducted to the driver circuit through the parasitic inductor by the source path between the Kelvin source terminal and the source terminal, which contains this parasitic inductor, and the incorporation of a resistor unit connected in parallel to this inductor in the second driver path. This voltage counteracts the gate-source voltage and therefore limits a current change rate (di/dt) when switching the semiconductor switch.

The switching behavior of the semiconductor switch is characterized by a temporal offset between the current and voltage changes when switching on and off. This effect is the result of the interaction of the different phases, specifically the dv/dt and di/dt phases, which are affected by parasitic inductance.

Switching the semiconductor off starts when voltage arrives at the drain-source terminal, to which the dv/dt phase belongs. Commutation first begins when the semiconductor has received all of the intermediate circuit voltage.

When the semiconductor is switched on, the process is reversed. First, the current flow changes, because the semiconductor begins to conduct. The quick increase in current forms the di/dt phase. After the current flow diminishes, the voltage between the drain and the source stabilizes, completing the dv/dt phase of the switching-off process.

Parasitic inductance has a substantial effect on the switching process during the di/dt phase, both when switching on and off. The inductor in the source path reduces the switching speed, because it allows for a direct feedback to the gate-source voltage in the semiconductor. This feedback is a condition of L*di/dt, which only acts on the gate-source voltage during the di/dt phase.

When switching off, di/dt is negative, changing the voltage at the parasitic inductor and increasing the gate-source voltage. This increase in voltage slows the di/dt phase, thus reducing the speed at which the semiconductor is switched off. This lowers the current change rate when switching off.

When switching on, di/dt is positive, and there is a voltage change at the parasitic inductor, reducing the gate-source voltage. This slows the di/dt phase, reducing the increase in current when switching the semiconductor on.

Consequently, feedback effects act on the parasitic inductor when switching both on and off.

The advantage with this is that it is possible to reduce the di/dt switching edges, while having little or no effect on the dv/dt switching edges. Consequently, the current change rate can be controlled in a targeted manner, resulting in a more efficient switching. Furthermore, the reduced di/dt switching edges limit the voltage surges when switching off, such that the power semiconductor can be operated within a safe range. The reduction in the di/dt switching edges also lowers the occurrence of oscillation when switching on, thus reducing electromagnetic emissions. Compared with conventional approaches, increasing the gate resistance also reduces switching losses, because this has little or no effect on the dv/dt switching edges.

In a preferred embodiment, the resistor unit contains a first resistor between the driver circuit and the Kelvin source terminal, and a second resistor between the driver circuit and the additional source terminal.

These resistors form an effective gate resistor for the driver circuit. The voltage of the negative feedback through the parasitic inductor acting on the gate-source voltage during the di/dt phase when switching off is defined by the relationship between the first and second resistors. These resistors are connected in parallel.

By dividing the resistor unit into two separate resistors, it is possible to set the current change rate, such that the switching performance can be optimized.

In another preferred embodiment, the first resistor has a higher resistance than the second.

The relationship between the two resistors defines the extent of the negative feedback of the voltage that acts through the parasitic inductor on the gate-source voltage during the di/dt phase. If the second resistor has a lower resistance than the first, a larger portion of the inducted voltage has an effect, thus reducing the di/dt.

The advantage with this is that the limitation on the current change rate reduces electromagnetic emissions by minimizing oscillations.

Furthermore, a lower di/dt lowers the switching-off voltage, protecting the semiconductor and ensuring that it is operated within a safe range. Lastly, by optimizing switching losses, efficiency remains high, because the dv/dt edges remain unchanged, thus preventing additional losses.

In a preferred embodiment, the additional source terminal for the semiconductor switch is formed by spring contacts, clamps or soldering.

The advantage with this is that the additional source terminal obtained with spring contacts, clamps or soldering forms a simple, flexible, and inexpensive solution. These connections are reliable and form a low amperage connection that can compensate for mechanical loads resulting from thermal expansion or vibrations, thus increasing the service life and durability.

In another preferred embodiment, the parasitic inductor is formed by conductor path routing on a printed circuit board.

“Conductor path routing” in this context refers to a targeted design and placement of conductor paths on a printed circuit board that has an effect on parasitic inductance. The targeted design and sizing of the conductor paths enables targeted effects on the inductive properties of the parasitic inductor. This is particularly the case if the current paths of the half-bridges are on the printed circuit board. If these current paths are not on the printed circuit board (formed by copper rails or busbars), the parasitic inductor is formed by the physical shape of the copper rails or busbars.

By coordinating the parasitic inductance, it is possible to adjust the negative feedback of the voltage.

In another preferred embodiment, the second driver path is connected to a ground in the driver circuit. The resistor unit forms the gate resistor for the driver circuit.

In another preferred embodiment, the semiconductor switch is a SiC-MOSFET, Si-IGBT, or GaN switch.

Gallium nitride (GaN) and silicon carbide (SiC) semiconductor switches have higher values for the critical electric field strengths, and better thermal conductance than other switching elements. Consequently, they can be operated at higher switching speeds with lower losses. SiC semiconductors can also withstand higher voltages, resulting in higher power densities.

In another preferred embodiment, the source terminal forms the additional source terminal.

When the source terminal forms the additional source terminal, the power semiconductor module design is simplified.

In another preferred embodiment, the resistor unit is part of the driver circuit.

The advantage with this is that it is more compact, increasing the reliability by reducing the number of connection points.

In a preferred embodiment, the power semiconductor module contains an additional semiconductor switch, and the two semiconductors are switched alternatingly in a half-bridge circuit.

The traction converter obtained with the present disclosure has the same advantages as those described for the power semiconductor module obtained with the present disclosure.

The present disclosure shall be described and explained in greater detail below based on selected exemplary embodiments in reference to the drawings.

### BRIEF DESCRIPTION OF THE DRAWINGS

FIG. 1 shows a simplified schematic illustration of a vehicle in a side view, with a traction converter obtained with the present disclosure containing a power semiconductor module obtained with the present disclosure;

FIG. 2 shows a schematic illustration the power semiconductor module obtained with the present disclosure;

FIG. 3 shows a schematic illustration of a half-bridge circuit;

FIG. 4a shows a schematic power semiconductor module according to a prior approach; and

FIG. 4b shows another exemplary embodiment of the power semiconductor module obtained with the present disclosure.

### DETAILED DESCRIPTION

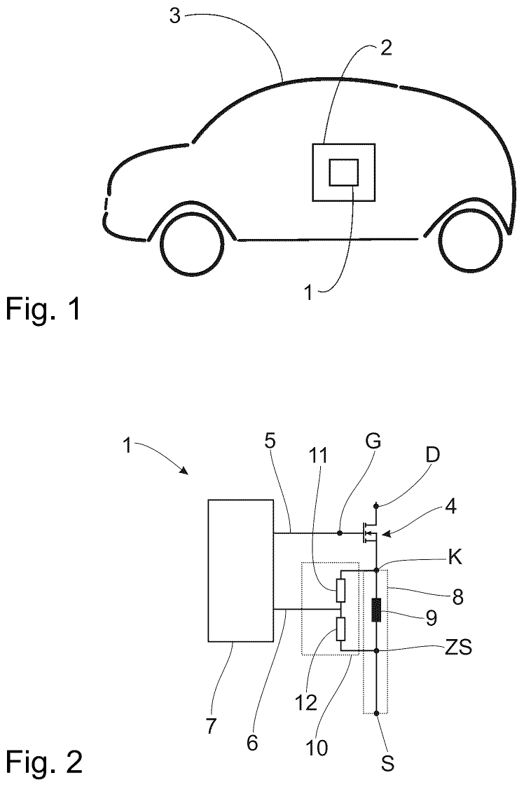

FIG. 1 shows a simplified schematic illustration of a vehicle 3 in a side view, with a traction converter 2 obtained with the present disclosure containing a power semiconductor module 1 obtained with the present disclosure. The traction converter 2 is between the battery and the electric motor and converts direct current from the battery into the alternating current necessary for the electric motor.

FIG. 2 shows a schematic illustration of a power semiconductor module 1 obtained with the present disclosure. The power semiconductor module 1 contains a semiconductor switch 4 with a drain terminal D, source terminal S, Kelvin source terminal K and gate terminal G.

A first driver path 5 connects the gate terminal G on the semiconductor switch 4 to a driver circuit 7. Another driver path 6 connects the source terminal S to the driver circuit 7. The semiconductor switch 4 is switched on and off by the driver circuit 7.

A source path 8 connects the Kelvin source terminal K and the source terminal S. This source path 8 is formed with an additional source terminal ZS and forms a parasitic inductor 9 between the Kelvin source terminal K and the additional source terminal ZS.

A resistor unit 10 is connected in parallel to the parasitic inductor 9 in the second driver path 6. This resistor unit 10 conducts voltage generated during the current-changing phase by the parasitic inductor 9 to the driver circuit 7. This limits the current change rate (di/dt) during the switching of the semiconductor switch 4.

The resistor unit 10 contains a first resistor 11 in the second driver path 6 between the driver circuit 7 and the Kelvin source terminal K. There is also a second resistor 12 in the second driver path 6 between the driver circuit 6 and the additional source terminal ZS. The two resistors are connected to one another and the driver circuit by a connection to the driver circuit. The first resistor 11 has a higher resistance than the second resistor 12.

The driver circuit 7 therefore connects the first resistor 11 and second resistor 12 with the second driver path 6.

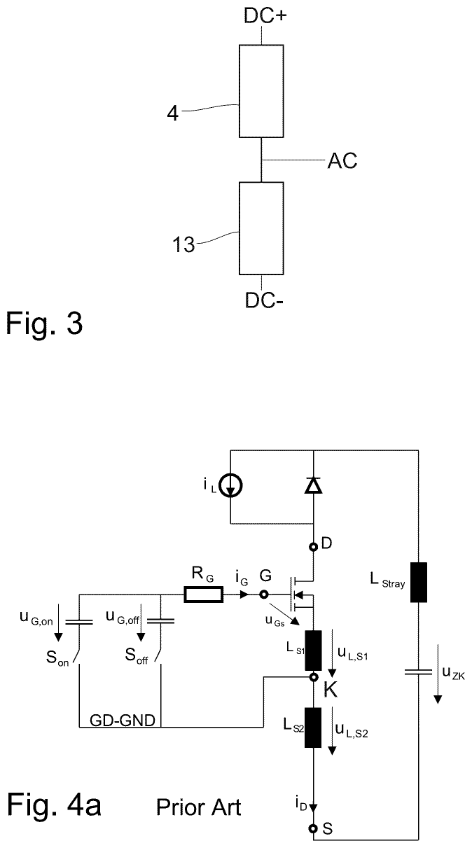

FIG. 3 schematically shows a half-bridge circuit. A first semiconductor 4 and second semiconductor 13 can be placed in a half bridge in the power semiconductor module obtained with the present disclosure. The connection and control thereof is illustrated in FIG. 2. The semiconductor switches 4, 13 are switched alternatingly in the semiconductor circuit to generate an AC voltage.

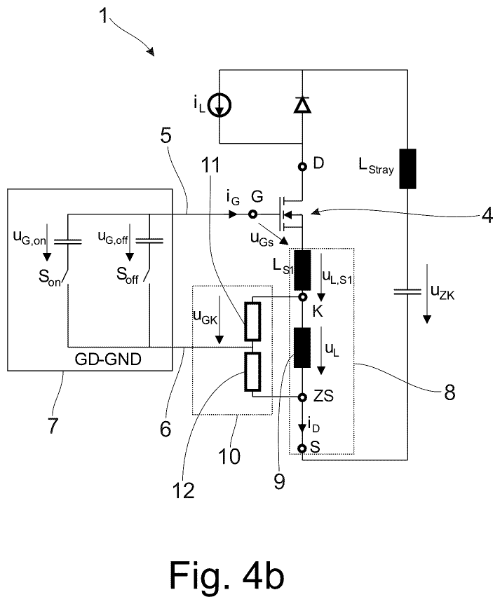

FIG. 4a schematically shows a power semiconductor module according to the prior art. In this case, the gate resistor Rg is in a first driver path, and the driver circuit is placed directly at the Kelvin source terminal.

FIG. 4b shows an exemplary embodiment of the power semiconductor module 1 obtained with the present disclosure, with a semiconductor switch 4. The source path 8 forms a parasitic inductor 9. Unlike in the prior art, shown in FIG. 4a, the driver circuit 7 is connected by a second driver path 6 to a resistor unit 10 that contains a first resistor 11 between the driver circuit 7 and the Kelvin source terminal (K), and a second resistor 12 between the driver circuit 7 and the additional source terminal ZS. The first driver path 5 does not have a gate resistor Rg, and the gate resistor is formed instead by the resistor unit 10 in the second driver path 6.

The present disclosure has been comprehensively described and explained in reference to the drawings. The description and explanation are to be understood as examples and not limiting. The present disclosure is not limited to the disclosed embodiments. Other embodiments or variations can be derived by the person skilled in the art when using the present disclosure and through a precise analysis of the drawings, the disclosure, and the following claims.

The words “comprise” and “with” in the claims do not exclude the presence of other elements or steps. The indefinite articles “a” or “an” do not exclude the presence of a plurality. A single element or unit can execute the function of numerous units specified in the claims. Simply specifying certain measures in numerous different dependent claims is not to be understood to mean that a combination of these measures cannot also be used advantageously. Reference symbols in the claims are not to be understood as limiting.

### REFERENCE SYMBOLS

1 power semiconductor module
2 traction converter
3 vehicle
4 semiconductor switch
5 first driver path
6 second driver path
7 driver circuit
8 source path
9 parasitic inductor
10 resistor unit
11 first resistor
12 second resistor
13 additional semiconductor switch
D drain terminal
S source terminal
ZS additional source terminal
G gate terminal
K Kelvin source terminal

1. A power semiconductor module for a traction converter, comprising:
a semiconductor switch with a drain terminal, source terminal, Kelvin source terminal, and gate terminal;
a first driver path configured to connect the gate terminal to a driver circuit and a second driver path configured to connect the source terminal to the driver circuit, in order to switch the semiconductor switch;
a source path between the Kelvin source terminal and the source terminal, wherein the source path comprises an additional source terminal, and wherein the source path forms a parasitic inductor between the Kelvin source terminal and the additional source terminal; and
a resistor unit in the second driver path that is connected in parallel to the parasitic inductor and is configured to conduct voltage generated by the parasitic inductor during a current-changing phase to the driver circuit to limit a current change rate while switching the semiconductor switch.

2. The power semiconductor module according to claim 1,
wherein the resistor unit comprises a first resistor between the driver circuit and the Kelvin source terminal, and a second resistor between the driver circuit and the additional source terminal.

3. The power semiconductor module according to claim 2,
wherein the first resistor has a higher resistance than the second resistor.

4. The power semiconductor module according to claim 1,
wherein the additional source terminal for the semiconductor switch is formed by a spring contact, clamp, or solder.

5. The power semiconductor module according to claim 1,
wherein the parasitic inductor is formed by a conductor path routing on a printed circuit board.

6. The power semiconductor module according to claim 1,
wherein the second driver path is connected to a ground in the driver circuit.

7. The power semiconductor module according to claim 1,
wherein the resistor unit is part of the driver circuit.

8. The power semiconductor module according to claim 1,
wherein the source terminal forms the additional source terminal, and/or the semiconductor switch is a SiC-MOSFET, Si-IGBT, or GaN switch.

9. The power semiconductor module according to claim 1, comprising:
a second semiconductor switch, wherein the first semiconductor switch and the second semiconductor switch are switched alternatingly in a half-bridge circuit.

10. A traction converter for a vehicle, comprising:
the power semiconductor module according to claim 1.
